(19) United States
(12) Patent Application Publication
(10) Pub. No.: US 2013/0032837 A1
(43) Pub. Date: Feb. 7, 2013

(54) Fluorescent Coating and a Method for Making the Same

(71) Applicants: Yang-Kuao Kuo, Taoyuan County (TW); Hsin-Liang Chen, Taoyuan County (TW); Chun-Yen Lo, Taoyuan County (TW); Chin-Peng Wang, Taoyuan County (TW)

(72) Inventors: Yang-Kuao Kuo, Taoyuan County (TW); Hsin-Liang Chen, Taoyuan County (TW); Chun-Yen Lo, Taoyuan County (TW); Chin-Peng Wang, Taoyuan County (TW)

(73) Assignee: Chung-Shan Institute of Science and Technology, Armaments, Bureau, Ministry of National Defense, Taoyuan County (TW)

(21) Appl. No.: 13/238,283

(22) Filed: Sep. 21, 2011

(30) Foreign Application Priority Data
Aug. 4, 2011 (TW) 100127711

(51) Int. Cl. H01L 33/50; H01L 33/44

(52) U.S. Cl. 257/98; 438/29; 257/E33.061; 257/E33.001

(57) ABSTRACT

Disclosed is a fluorescent coating and a method for making the same. At first, fluorescent powder is mixed with an anti-electrostatic solution. The mixture is cleared of impurities before it is dried and sintered. Thus, the fluorescent powder is coated with the anti-electrostatic material. The fluorescent powder coated with the anti-electrostatic material is plated on a side of a light-emitting diode (“LED”) chip by electrophoresis, thus forming a mixing zone on the side of the LED chip. Hence, the mixing zone is not vulnerable to deterioration or itiolation when it is subjected to heat in use. Accordingly, the life of the LED chip is long, and the illumination of the LED chip is high.

### BACKGROUND OF INVENTION

1. Field of Invention

The present invention relates to a fluorescent coating and a method for making the same, more particularly, to a fluorescent coating for use in an LED device and a method for making the same.

2. Related Prior Art

White light LED devices are generally environmentally friendly, energy efficient, compact, light and save, respond fast, operate at low voltages, and last for long periods of time. Therefore, white light LED devices are expected to become the mainstream for illumination in the 21^{st} century. There are several manners to cause LED devices to emit white light. For example, an LED chip can be coated fluorescent powder. There are three manners to emit white light with an LED chip coated with fluorescent powder.

At first, a blue light LED chip is coated with yellow light fluorescent powder. The blue light LED chip can be actuated to emit blue light that excites the yellow light fluorescent powder to emit yellow light. Then, the blue light emitted from the LED chip is mixed with the yellow light emitted from the yellow light fluorescent powder to provide white light. A problem encountered in this approach is that the emission spectrum of Ce3+ ions included in the yellow light fluorescent powder is not a continuous spectrum. Therefore, the color rendering is poor, and the emission efficiency is low, leaving a need for low color temperature illumination unsatisfied.

Secondly, a blue light LED chip is coated with green light fluorescent powder and red light fluorescent powder. The blue light LED chip can be actuated to emit blue light that excites the green light fluorescent powder to emit green light and excites the red light fluorescent powder to emit red light. The blue light, the green light and the red light are mixed with one another to provide white light. A problem with this approach is that the conversion rate of the fluorescent powder is low.

Thirdly, a purple or ultraviolet light LED chip is coated with at least three types of fluorescent powder. The purple or ultraviolet light LED chip can be actuated to emit purple light of which the wavelength is 380 to 410 nm or ultraviolet light of which the wavelength is 370 to 380 nm that excites the three types of fluorescent powder to emit the tricolor of light. This approach is advantageous over the foregoing two approaches. A problem with this approach is that the conversion rates with the three types of fluorescent powder are low. Moreover, the red light fluorescent powder and the green light fluorescent powder are made of sulfide. Therefore, the red light fluorescent powder and the green light fluorescent powder are unstable regarding the emission of light. That is, the luminous decay is serious.

Currently, in a process for making an LED, fluorescent powder is mixed with optically clear adhesive. For example, yellow light fluorescent powder is mixed with the optically clear adhesive. The mixture is dripped into the LED. An advantage of this approach is simple. There is however a problem with this approach. The optically clear adhesive is a high-molecular organic compound. When the LED is used for a long period of time, a lot heat is produced in the LED. Without effective control over the heat, the optically clear adhesive would be degraded or structurally modified. Therefore, the life of the LED is reduced.

The present invention is therefore intended to obviate or at least alleviate the problems encountered in prior art.

### SUMMARY OF INVENTION

It is an objective of the present invention to provide an efficient and reliable LED device.

To achieve the foregoing objective, the LED device includes an LED chip and a fluorescent coating provided on the LED chip. The fluorescent coating includes fluorescent grains each coated with a metal oxide layer.

In the LED device, the LED chip may be a blue light LED chip.

In the LED device, the fluorescent coating may be provided on the LED chip by electrophoresis.

In the LED device, the fluorescent grains may be conductive yellow light fluorescent grains.

In the LED device, the metal oxide layers may be made of antimony doped tin oxide or indium tin oxide in the order of nanometer.

It is another objective of the present invention to provide a method for making an efficient and reliable LED device.

To achieve the foregoing objective, the method includes the steps of providing an LED chip, mixing fluorescent grains with a metal oxide solution to provide a liquid mixture, removing impurities from the liquid mixture, drying the liquid mixture, sintering the mixture to provide fluorescent grains each coated with a metal oxide layer, and coating the LED chip with the fluorescent grains coated with the metal oxide layers, thus forming a fluorescent coating on the LED chip.

In the method, the fluorescent grains may be conductive yellow light fluorescent grains.

In the method, the metal oxide layers may be made of antimony doped tin oxide or indium tin oxide in the order of nanometer.

In the method, the step of mixing the fluorescent grains with the metal oxide solution may include the step of executing ultrasonic oscillation and magnet stirring.

In the method, the step of removing the impurities from the liquid mixture may include the step of executing a high speed refrigerated centrifugal process.

In the method, the step of drying the liquid mixture may be executed at low temperature to remove solvents with low boiling points.

In the method, the LED chip may be a blue light LED chip.

In the method, the step of coating the LED chip with the fluorescent coating may include the step of providing an electrophoresis tank. The LED chip is provided at an end of the electrophoresis tank while the fluorescent grains coated with the metal oxide layers are provided at an opposite end of the electrophoresis tank. The electrophoresis tank is subject to a voltage for causing the fluorescent grains coated with the metal oxide to drift to and be eventually coated on the LED chip.

Other objectives, advantages and features of the present invention will be apparent from the following description referring to the attached drawings.

### BRIEF DESCRIPTION OF DRAWINGS

The present invention will be described via detailed illustration of the preferred embodiment referring to the drawings wherein:

FIG. 1 is a cross-sectional view of a fluorescent coating according to the preferred embodiment of the present invention;

FIG. 2 is an enlarged partial cross-sectional view of the fluorescent coating shown in FIG. 1;

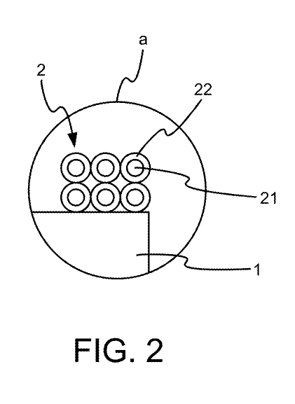

FIG. 3 is a flow chart of a first step of a method for making the fluorescent coating shown in FIG. 1;

FIG. 4 is a flow chart of a second step of a method for making the fluorescent coating shown in FIG. 1; and

FIG. 5 is a flow chart of a third step of a method for making the fluorescent coating shown in FIG. 1.

### DETAILED DESCRIPTION OF PREFERRED EMBODIMENT

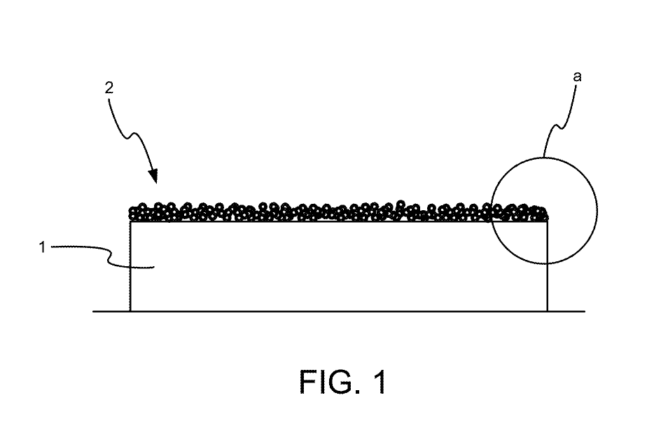

Referring to FIG. 1, there is shown an LED device including an LED chip 1 and a fluorescent coating 2 according to the preferred embodiment of the present invention. The fluorescent coating 2 includes a plurality of fluorescent grains 21 and a plurality of metal oxide layers 22. Each of the fluorescent grains 21 is covered by a related one of the metal oxide layers 22.

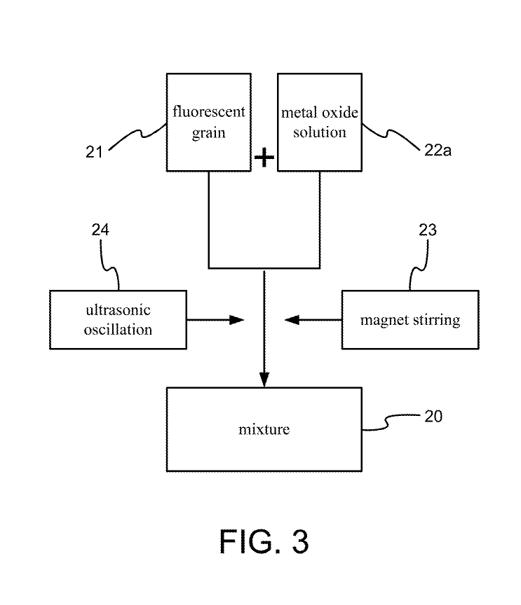

Referring to FIGS. 3 through 5, there is shown a method for making the LED device, which includes the LED chip and the fluorescent coating 2.

Referring to FIG. 3, the fluorescent grains 21 are mixed with a metal oxide solution 22a by ultrasonic oscillation 23 used together with magnet stirring 24, thus providing a liquid mixture 20. The fluorescent grains 21 are electrically conductive yellow light fluorescent grains for example.

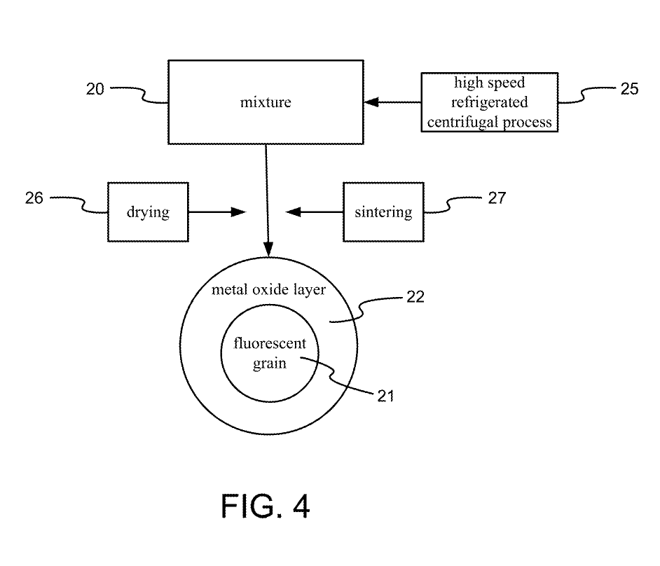

Referring to FIG. 4, a high speed refrigerated centrifugal process 25 is used to remove residual adhesive or other impurities from the liquid mixture 20. At low temperature, drying 26 is executed to remove solvents with low boiling points. Then, sintering 27 is executed to provide the fluorescent grains 21 coated with the metal oxide layers 22. The metal oxide layers 22 may be made of antimony-doped tin oxide (“ATO”) in the order of nanometer or indium tin oxide (“ITO”) in the order of nanometer.

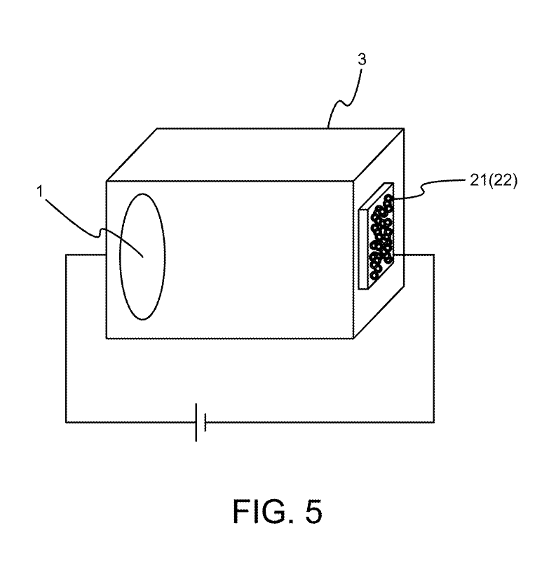

Referring to FIG. 5, there is provided a blue light LED chip 1. By electrophoresis, the LED chip 1 is coated with the fluorescent grains 21, which are coated with the metal oxide layers 22. In the electrophoresis, there is provided an electrophoresis tank 3, and the LED chip 1 is provided at an end of the electrophoresis tank 3 while the fluorescent grains 21 coated with a metal oxide layers 22 are provided at an opposite end of the electrophoresis tank 3. The electrophoresis tank 3 is subject to a voltage so that the fluorescent grains 21 coated with the metal oxide layers 22 drift to and are eventually coated on the LED chip 1 by the electrophoresis. Thus, the LED chip 1 is coated with the fluorescent coating 2.

As described above, the fluorescent grains 21 are coated with the metal oxide layer 22 made of ATO or ITO in the order of nanometer. Moreover, the fluorescent grains 21 are coated on the LED chip 1 by the electrophoresis. Hence, there is no need for using optically clear adhesive, thus overcoming the problem related to a reduced life caused by thermal degradation or structural modification of optically clear adhesive after a long period of time of use. In accordance, the efficiency of the LED of the present invention is high, and the life of the LED of the present invention is long.

The present invention has been described via the detailed illustration of the preferred embodiment. Those skilled in the art can derive variations from the preferred embodiment without departing from the scope of the present invention. Therefore, the preferred embodiment shall not limit the scope of the present invention defined in the claims.

1. An LED device including:
an LED chip; and
a fluorescent coating provided on the LED chip, the fluorescent coating including fluorescent grains each coated with a metal oxide layer.

2. The LED device according to claim 1, wherein the LED chip is a blue light LED chip.

3. The LED device according to claim 1, wherein the fluorescent coating is provided on the LED chip by electrophoresis.

4. The LED device according to claim 1, wherein the fluorescent grains are conductive yellow light fluorescent grains.

5. The LED device according to claim 1, wherein the metal oxide layers are made of a material selected from the group consisting of antimony doped tin oxide and indium tin oxide in the order of nanometer.

6. A method for making an LED device including the steps of:
providing an LED chip;
mixing fluorescent grains with a metal oxide solution to provide a liquid mixture;
removing impurities from the liquid mixture;
drying the liquid mixture;
sintering the mixture to provide fluorescent grains each coated with a metal oxide layer; and
coating the LED chip with the fluorescent grains coated with the metal oxide layers, thus forming a fluorescent coating on the LED chip.

7. The method for making an LED device according to claim 6, wherein the fluorescent grains are conductive yellow light fluorescent grains.

8. The method for making an LED device according to claim 6, wherein the metal oxide layers are made of a material selected from the group consisting of antimony doped tin oxide and indium tin oxide in the order of nanometer.

9. The method for making an LED device according to claim 6, wherein the step of mixing the fluorescent grains with the metal oxide solution includes the step of executing ultrasonic oscillation and magnet stirring.

10. The method for making an LED device according to claim 6, wherein the step of removing the impurities from the liquid mixture includes the step of executing a high speed refrigerated centrifugal process.

11. The method for making an LED device according to claim 6, wherein the step of drying the liquid mixture is executed at low temperature to remove solvents with low boiling points.

12. The method for making an LED device according to claim 6, wherein the LED chip is a blue light LED chip.

13. The method for making an LED device according to claim 6, wherein the step of coating the LED chip with the fluorescent coating includes the step of providing an electrophoresis tank, wherein the LED chip is provided at an end of the electrophoresis tank while the fluorescent grains coated with the metal oxide layers are provided at an opposite end of the electrophoresis tank, wherein the electrophoresis tank is subject to a voltage for causing the fluorescent grains coated with the metal oxide to drift to and be eventually coated on the LED chip.
